(19) United States
(12) Patent Application Publication
(10) Pub. No.: US 2006/0205103 A1
(43) Pub. Date: Sep. 14, 2006

(54) Methods for repairing and manufacturing display device

(76) Inventors: Takuo Tamura, Yokohama (JP); Hiroshi Kikuchi, Zushi (JP); Yasushi Sano, Yokohama (JP); Masakazu Sagawa, Inagi (JP); Yoshiro Mikami, Hitachiohta (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/213,748

(22) Filed: Aug. 30, 2005

(30) Foreign Application Priority Data
Aug. 30, 2004 (JP) 2004-249864

(51) Int. Cl. H01L 21/00; H01L 21/82

(52) U.S. Cl. 438/30; 438/132

(57) ABSTRACT

For inhibiting generation of pixels that could not be displayed in a line in a display screen of an electron emission display comprising the pixels each provided with an electron source in which a first electrode at a signal line side and a second electrode at a scanning line side are joined through an isolating layer (electron acceleration layer), the present invention cuts off continuity between the first electrode and the second electrode which are short-circuited caused by a defect, so that the electron source with the defect is isolated from other electron sources. In the electron source with a defect, for example, a portion of the second electrode surrounding the above-mentioned defect thereof is excised by laser.

The present application claims priority from Japanese application JP2004-249864 filed on Aug. 30, 2004, the content of which is hereby incorporated, by reference into this application.

### BACKGROUND OF THE INVENTION

1. Field of the Invention

The present invention relates to a display device, especially to a method for repairing defects of a substrate (display substrate) on whose main surface electron emitting elements (electron emission sources) that correspond to its pixels are formed.

2. Description of the Related Art

Japanese Patent Laid-open Publication (referred to as JP-A, hereinafter) No. 1991-55738 (and its counterpart U.S. Pat. No. 5,569,974) and JP-A-2001-255845 (and its counterpart U.S. Pat. No. 6,404,135) each describe a display panel used for a field emission type image display device (Field Emission Display) and its manufacturing process. The display panel described in JP-A-1991-55738 is constructed by arranging electron sources each serving as a display element at respective positions where the scanning lines intersect signal lines to form a matrix. Each electron source will generate an electron beam when a predetermined voltage is impressed between the scanning line side electrode and the signal line side electrode. Therefore, by an appropriate voltage waveform impressed on the signal lines, an arbitrary electron source is made to generate an electron beam, and a desired picture can be displayed.

### SUMMARY OF THE INVENTION

However, in the display panel manufactured by the manufacturing process described in the JP-A-1991-55738, there is a case where pixels that could not be displayed appear in a line.

The present invention is made in view of the above-mentioned situation, and the object of the invention is to provide a technology of inhibiting the generation of pixels that could not be displayed in a line.

In order to solve the problem, the present invention aims repair at a display substrate on which display elements were formed. In an electron emission type display device represented as a field emission type image display device, the “display substrate” is described as a member thereof having a plurality of electron emitting elements (electron emission sources) formed on an area of its main surface corresponding to a display screen thereof. In this display device (display panel), the display substrate described above is arranged in opposition to another substrate mutually. A material (e.g. a fluorescent material) which emits light when receiving electrons emitted from the electron emitting elements is formed on a main surface of the another substrate. The display device described above displays an image by means of luminescence of the main surface of the another substrate in accordance with a pattern of electron emission by the plurality of electron emitting elements arranged on the main surface of the display substrate. In the display device thus operating, the “display substrate” mentioned above is also described as an electron source substrate or a cathode substrate, and the “another substrate” mentioned above is also described as a display side substrate or an anode substrate. Therefore, the scope of the present invention described as a method for repairing a display device in the present specification is extended to a repairing method of the display device characterized by a repairing process of the display substrate and a method for manufacturing a display device including a repairing process of the display substrate.

On the thus premise, an example of the method, for repairing a display substrate (the method for repairing a display device, the method for manufacturing a display device) according to the present invention is applied to ones of electron emitting elements formed on the main surface of the display substrate (corresponding to pixels of the display device respectively, and described as “display elements”, hereinafter) each having, the scanning line side electrode and the signal line side electrode which are both connected thereto and short-circuited, and continuity between the scanning line side electrode and the signal line side electrode both corresponding to each of the ones of the electron emitting elements will be cut off. The scanning line side electrode and the signal line side electrode are formed on the main surface of the display substrate as well as the display elements (electron emitting elements), and control electron emission from the display elements corresponding thereto in response to electric inputs thereto. In a-display element having an MIM (Metal-Insulator-Metal) junction, the scanning line side electrode and the signal line side electrode are connected to respective metal layers that oppose to each other across an insulating layer. In a display element that serves as a pixel of the display device known as SED (Surface-conduction Electron-emitter Display), a conducting film is divided by a high resistance area formed by forming processing on the conducting film etc., a scanning line side electrode being connected to one of the conducting film and the signal line side electrode being connected to the other of the conducting film, respectively. At least either the scanning line side electrode or the signal line side electrode may be formed as a “wiring” that is connected electrically to the electrode of the display element corresponding thereto.

Describing the method for repairing a display substrate (the method for repairing a display device, the method for manufacturing a display device) according to the present invention more specifically, in the method for repairing a display substrate of an electron emission type display device (a field emission type display device) comprising an electron source having a structure in which a first electrode (a signal line side electrode), an insulating layer, and a second electrode (a scanning line side electrode) are stacked in this order cuts off continuity of the first electrode and the second electrode for an electron source having the first electrode and the second electrode which are short-circuited.

According to the present invention thus configured, a display element with a defect can be isolated. Thus, display elements being originally normal can operate normally, while the generation of the pixels that could not be displayed in a line is prohibited.

In the display device according to the present invention, the display substrate (cathode substrate) described above is joined to the another substrate (anode substrate) by opposing an area (display area) of the main surface thereof in which the plurality of electron emitting elements are formed to a main surface of the other substrate and through a sealing member so provided between the main surfaces as to enclose the area. The plural electron emitting elements formed on the main surface of the display substrate are disposed in a space that is surrounded by the main surface of the display substrate, the main surface of the another substrate, and the sealing member. The space is maintained at a pressure lower than the atmosphere of the display device (for example, a so-called vacuum state of 1×10⁻⁴ Pa or less).

### BRIEF DESCRIPTION OF THE DRAWINGS

FIG. 1 is a view for explaining the generation of electron beams in an electron source of the field emission display;

FIG. 2(a) is a plan view of a substrate, FIG. 2(b) is a sectional view taken along A-A′ line of FIG. 2(a), and FIG. 2(c) is a sectional view taken along B-B′ line of FIG. 2(a);

FIG. 3(a) is a plan view of the substrate, FIG. 3(b) is a sectional view taken along the A-A′ line of FIG. 3(a), and FIG. 3(c) is a sectional view taken along the B-B′ line of FIG. 3(a);

FIG. 4(a) is a plan view of the substrate, FIG. 4(b) is a sectional view taken along the A-A′ line of FIG. 4(a), and FIG. 4(c) is a sectional view taken along the B-B′ line of FIG. 4(a);

FIG. 5(a) is a plan view of the substrate, FIG. 5(b) is a sectional view taken along the A-A′ line of FIG. 5(a), and FIG. 5(c) is a sectional view taken along the B-B′ line of FIG. 5(a);

FIG. 6(a) is a plan view of the substrate, FIG. 6(b) is a sectional view taken along the A-A′ line of FIG. 6(a), and FIG. 6(c) is a sectional view taken along the B-B′ line of FIG. 6(a);

FIG. 7(a) is a plan view of the substrate, FIG. 7(b) is a sectional view taken along the A-A′ line of FIG. 7(b), and FIG. 7(c) is a sectional view taken along the B-B′ line of FIG. 7(a);

FIG. 8(a) is a plan view of the substrate, FIG. 8(b) is a sectional view taken along the A-A′ line of FIG. 8(a), and FIG. 8(c) is a sectional view taken along the B-B′ line of FIG. 8(a);

FIG. 9(a) is a plan view of the substrate, FIG. 9(b) is a sectional view taken along the A-A′ line of FIG. 9(a), and FIG. 9(c) is a sectional view taken along the B-B′ line of FIG. 9(a);

FIG. 10(a) is a plan view of the substrate, FIG. 10(b) is a sectional view taken along the A-A′ line of FIG. 10(a), and FIG. 10(c) is a sectional view taken along the B-B′ line of FIG. 10(a);

FIG. 11 is a plan view of the substrate of 6×6 dots;

FIG. 12(a) is a plan view of a substrate with a defect, and FIG. 12(b) is a sectional view taken along A-A′ line of FIG. 12(a);

FIG. 13(a) is a plan view of the display side substrate, FIG. 13(b) is a sectional view taken along C-C′ line of FIG. 13(a), and FIG. 13(c) is a sectional view taken along D-D′ line of FIG. 13(a);

FIG. 14(a) is a sectional view obtained by cutting the display panel along the A-A′ line in the main surface of the electron source substrate 200 of FIG. 10(a) that constitutes the display panel, and FIG. 14(b) is a sectional view obtained by cutting the display panel along the B-B′ line in the main surface of the electron source substrate 200 of FIG. 10(a);

FIG. 15 is a flowchart of a manufacturing process of a display panel;

FIG. 16 is a plan view of the display panel of 6×6 dots;

FIG. 17 is a view for explaining a voltage waveform to be impressed;

FIG. 18 is a view for explaining lighting of pixels of the display screen;

FIG. 19 is a view for explaining a voltage waveform to be impressed;

FIG. 20 is a view for explaining lighting of pixels of the display screen;

FIG. 21 is a view for explaining lighting of pixels of the display screen;

FIG. 22(a) is a plan view of a substrate according to a modification, FIG. 22(b) is a sectional view taken along A-A′ line of FIG. 22(a), and FIG. 22(c) is a sectional view taken along B-B′ line of FIG. 22(a);

FIG. 23(a) is a plan view of a substrate according to a modification, FIG. 23(b) is a sectional view taken along A-A′ line of FIG. 23(a), and FIG. 23(c) is a sectional view taken along B-B′ line of FIG. 23(a);

FIG. 24(a) is a plan view of a substrate according to a modification, FIG. 24(b) is a sectional view taken along A-A′ line of FIG. 24(a), and FIG. 24(c) is a sectional view taken along B-B′ line of FIG. 24(a); and

FIG. 25(a) is a plan view of a substrate with a defect, and FIG. 25(b) is a sectional view taken along A-A′ line of FIG. 25(a).

### DETAILED DESCRIPTION

Hereafter, embodiments of a method for repairing a display element and a method for manufacturing the same according to the present invention will be described with reference to the drawings. Before describing a manufacturing process of the display panel to which the one embodiment of the present invention was applied, an electron source used for the display panel of this embodiment will be explained.

The electron source used for the display panel of this embodiment is a thin film type electron source. The thin film type electron source has a basic structure such that three kinds of thin films, i.e., an upper electrode, an electron acceleration layer, and a bottom electrode, are stacked. The thin film type electron source will emit electrons into a vacuum from the surface of the upper electrode, when a voltage is impressed between the upper electrode and the bottom electrode. The thin film type electron sources include, for example, an MIM (Metal-Insulator-Metal) type such that metal-insulator-metal are stacked, an MIS (Metal-Insulator-Semiconductor) type such that metal-insulator-semiconductor are stacked, a metal-insulator-semiconductor-metal type, etc.

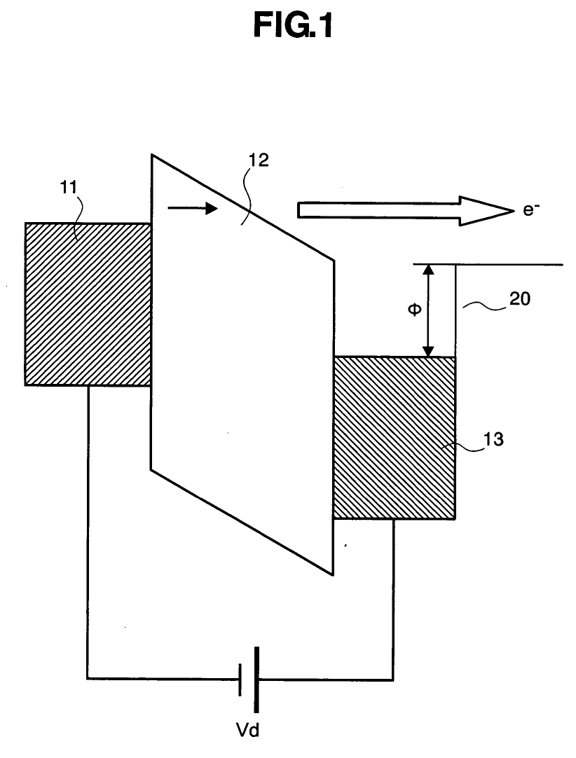

FIG. 1 is a view illustrating an operation principle of the thin film type electron source, taking the MIM type for an example. Assuming that a driving voltage is impressed between an upper electrode 13 and a bottom electrode 11 to set an electric field in the electron acceleration layer to 1 to 10 MV/cm, electrons in the vicinity of the Fermi level in the bottom electrode 11 penetrate the barrier due to a tunnel phenomenon, are injected into an electron acceleration layer 12, and become hot electrons. Although these hot electrons are scattered both in the electron acceleration layer 12 and in the upper electrode 13 and lose their energies, a part of hot electrons having energy equal to or more than the working function φ of the upper electrode 13 will be emitted into a vacuum 20. What other thin film type electron sources have in common is to accelerate electrons and emit them through the thin upper electrode 13.

Next, a manufacturing process of the display panel to which one embodiment of the present invention was applied will be described.

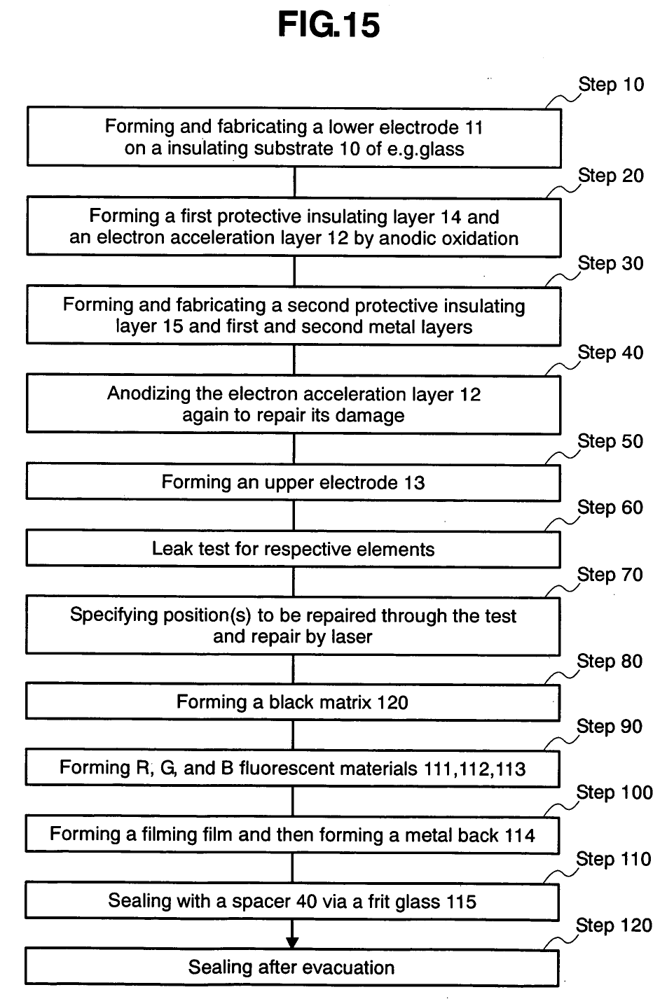

FIG. 15 is a flowchart of the manufacturing process of the display panel. Hereafter, explanation will be given according to this flowchart.

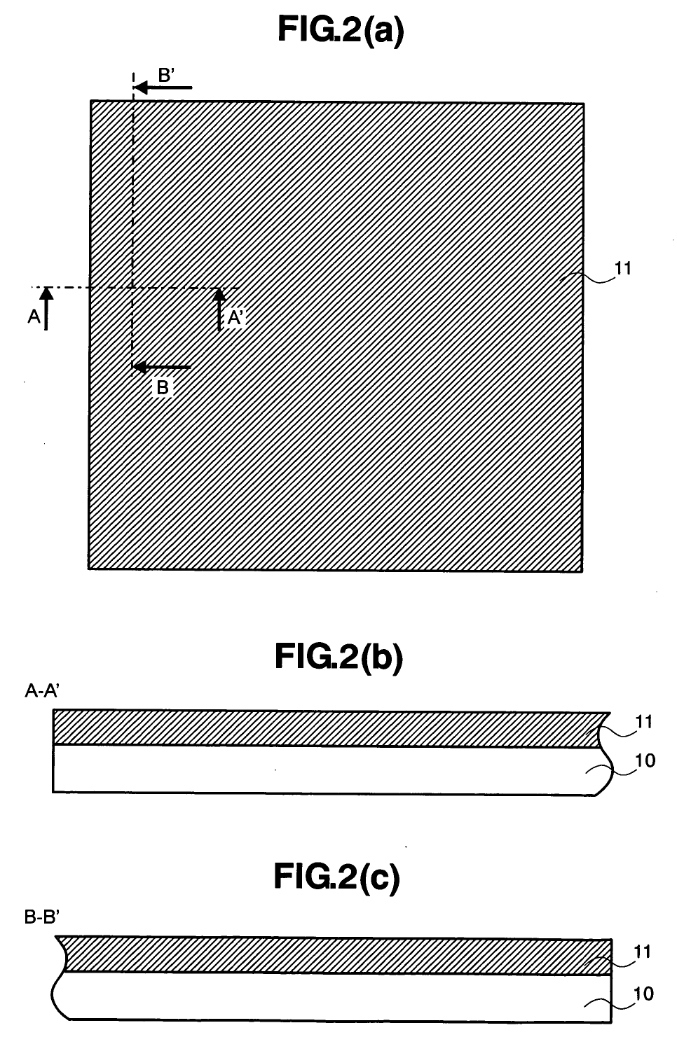

First, as shown in FIGS. 2(a)-2(c), the metal film 11 for a bottom electrode is formed on an insulating substrate 10, such as of glass. FIG. 2(a) is a plan view, FIG. 2(b) is a sectional view taken along A-A′ line, and FIG. 2(c) is a sectional view taken along B-B′ line.

As the bottom electrode material, Al, Al alloys, etc. can be used. The use of Al or Al alloys enables formation of an excellent insulating film by anodic oxidation. In this embodiment, an Al—Nd alloy obtained by doping 2 at % Nd was used. For film formation, the sputtering method is used, for example. Film thickness is about 300 nm.

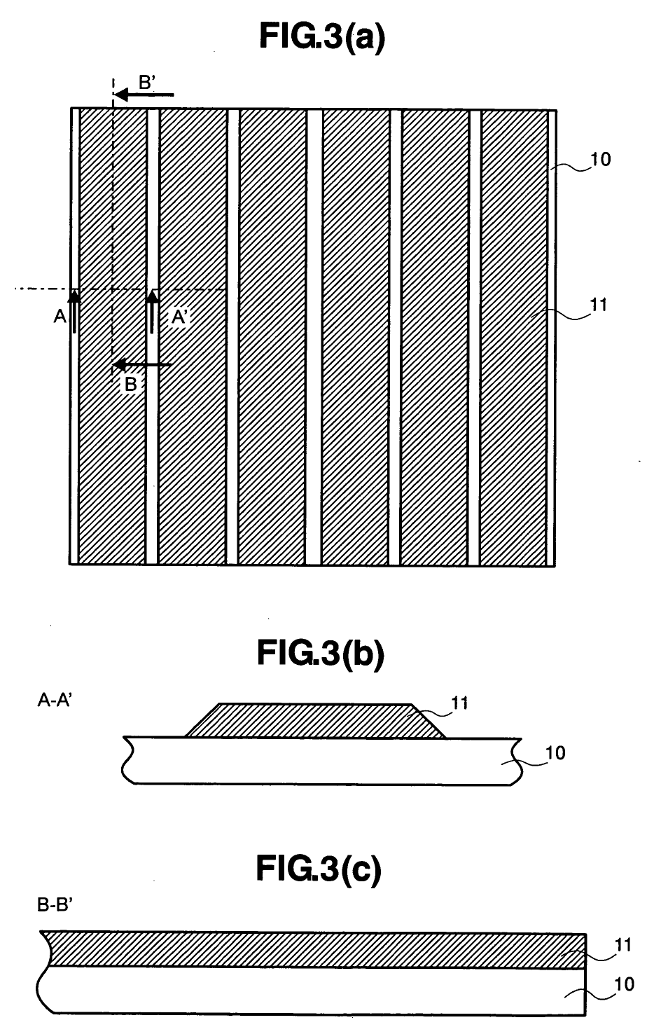

After the film formation, the stripe-shaped bottom electrode 11 is formed by a photolithography process and an etching process, as shown in FIGS. 3(a)-3(c). FIG. 3(a) is a plan view, FIG. 3(b) is a sectional view taken along the A-A′ line, and FIG. 3(c) is a sectional view taken along the B-B′ line. Note that, in this embodiment, the bottom electrode 11 serves as a signal line side electrode.

In the etching process, wet etching using, for example, a mixed solution of phosphoric acid, acetic acid, and nitric acid is employed (Step 10).

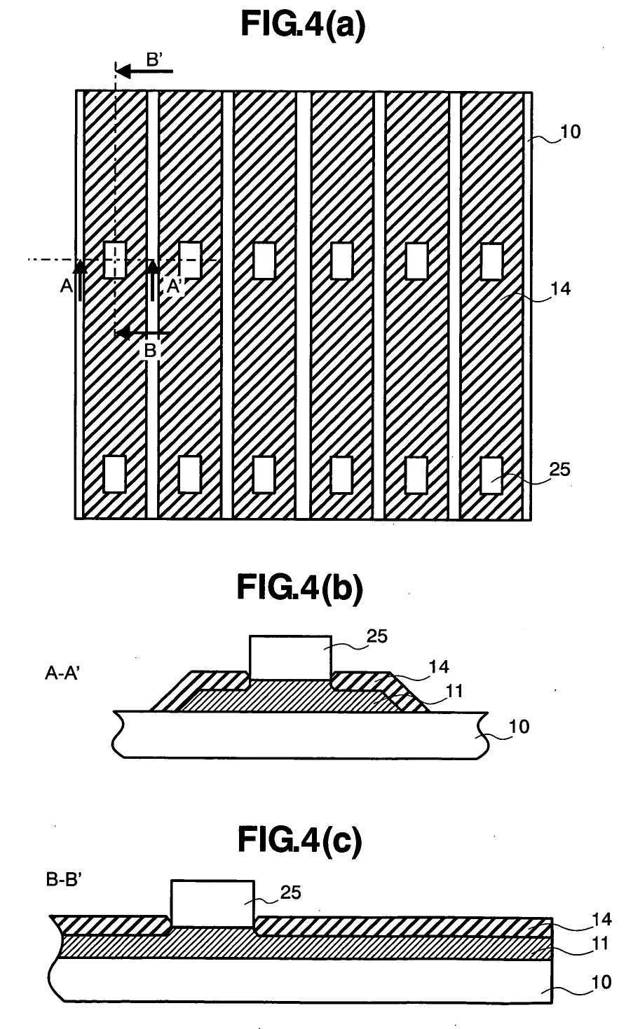

Next, as shown in FIGS. 4(a)-4(c), a first protective insulating layer 14 is formed. FIG. 4(a) is a plan view, FIG. 4(b) is a sectional view taken along the A-A′ line, and FIG. 4(c) is a sectional view taken along the B-B′ line.

The first protective insulating layer 14 plays a role of limiting an electron emission section and preventing an electric field from concentrating to an edge of the bottom electrode.

First, a portion in the bottom electrode 11 that will serve as the electron emission section is masked with a resist film 25, and other portion than this masked area is selectively anodized thickly so as to become the first protective insulating layer 14. For example, when a formation voltage is set to 100 V, the first protective insulating layer 14 of a thickness of about 136 nm is formed.

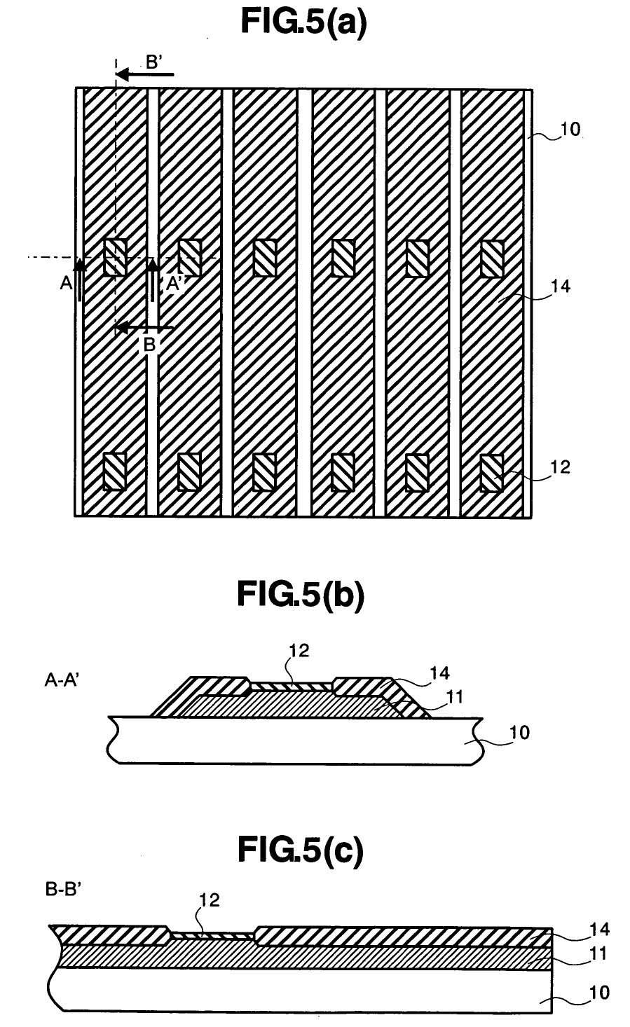

Next, as shown in FIGS. 5(a)-5(c), the electron acceleration layer 12 is formed. FIG. 5(a) is a plan view, FIG. 5(b) is a sectional view taken along the A-A′ line, and FIG. 5(c) is a sectional view taken along the B-B′ line.

First, the resist film 25 is removed, and the surface of the remaining bottom electrodes 11 is anodized to prepare the electron acceleration layer 12. For example, when a formation voltage is set to 6 V, the electron acceleration layer 12 of a thickness of about 10 nm is formed on the bottom electrode 11 (Step 20).

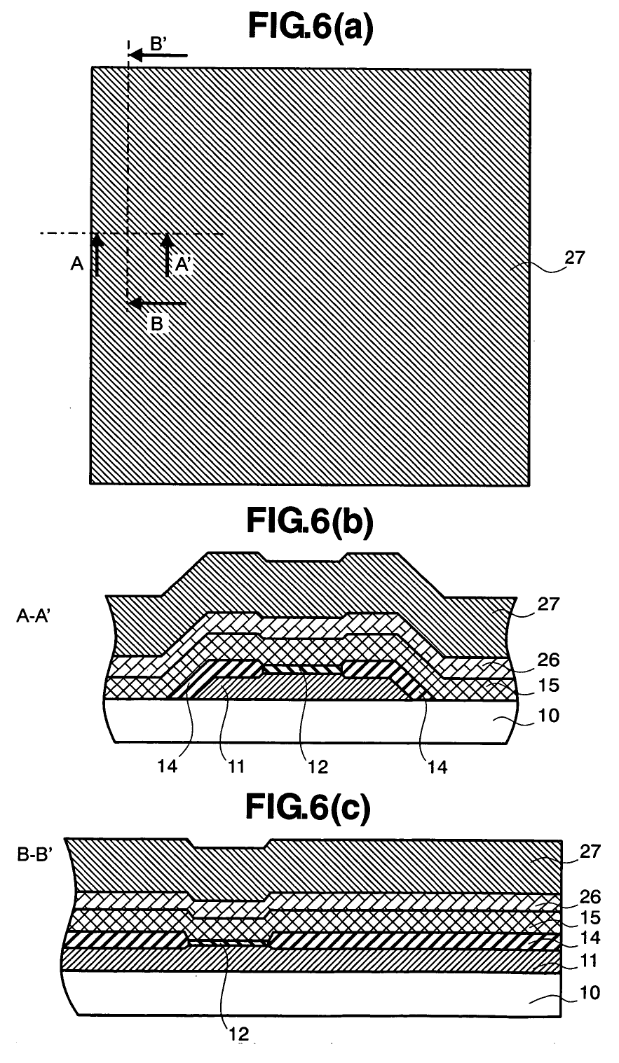

Next, as shown in FIGS. 6(a)-6(c), a second protective insulating layer 15 and an upper bus electrode that will serve as a feeder of the upper electrode 13 (a first metal layer 26 and a second metal layer 27) are formed and fabricated by, for example, a sputtering method etc. FIG. 6(a) is a plan view, FIG. 6(b) is a sectional view taken along the A-A′ line, and FIG. 6(c) is a sectional view taken along the B-B′ line.

The second protective insulating layer 15 plays a role of, when a pinhole exists in the protective insulating layer 14 formed by anodic oxidation, embedding the defect, thereby keeping insulation between the bottom electrode 11 and the upper bus electrode 26.

Silicon nitride etc. is used for the second protective insulating layer 15. Its film thickness is set to 40 nm.

In this embodiment, the upper bus electrodes (the first metal layer 26 and the second metal layer 27) serve as the scanning line side electrode.

Cr can be used as a material of the first metal layer 26. Al—Nd alloys can be used as materials of the second metal layer 27. Mo, W, Ti, Nb, etc. other than Cr can also be used for the first metal layer 26. Al, Cu, Cr, Cr, Cr alloys, etc. other than Al—Nd alloys can be used for the second metal layer 27. The film thickness of the first metal layer 26 is a few tens of nanometers. The film thickness of the second metal layer 27 is a few micrometers.

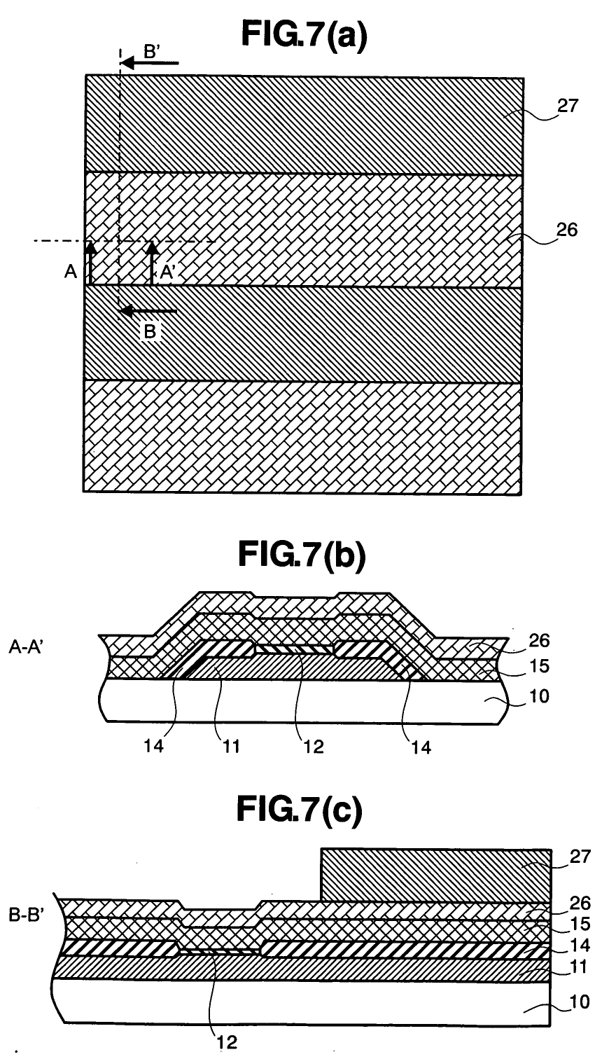

Next, as shown in FIGS. 7(a)-7(c), the second metal layer 27 is formed and fabricated by a photoetching process so as to become perpendicular to the bottom electrode 11. FIG. 7(a) is a plan view, FIG. 7(b) is a sectional view taken along the A-A′ line, and FIG. 7(c) is a sectional views taken along the B-B′ line. As an etchant, a mixed aqueous solution of phosphoric acid, acetic acid, and nitric acid and other solution can be used to the Al—Nd alloy of the second metal layer 27 etc.

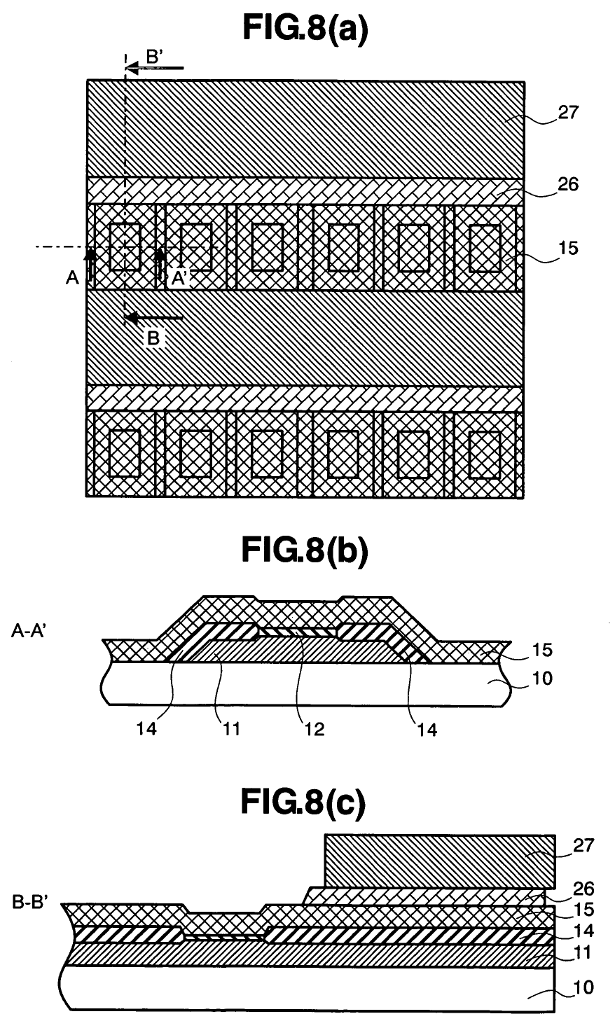

Next, as shown in FIGS. 8(a)-8(c), the first metal layer 26 is formed and fabricated by a photoetching process so as to become perpendicular to the bottom electrode 11. FIG. 8(a) is a plan view, FIG. 8(b) is a sectional view taken along the A-A′ line, and FIG. 8(c) is a sectional views taken along the B-B′ line. As an etchant, a solution of cerium ammonium nitrate and other solution can be used for Cr of the first metal layer 26 etc.

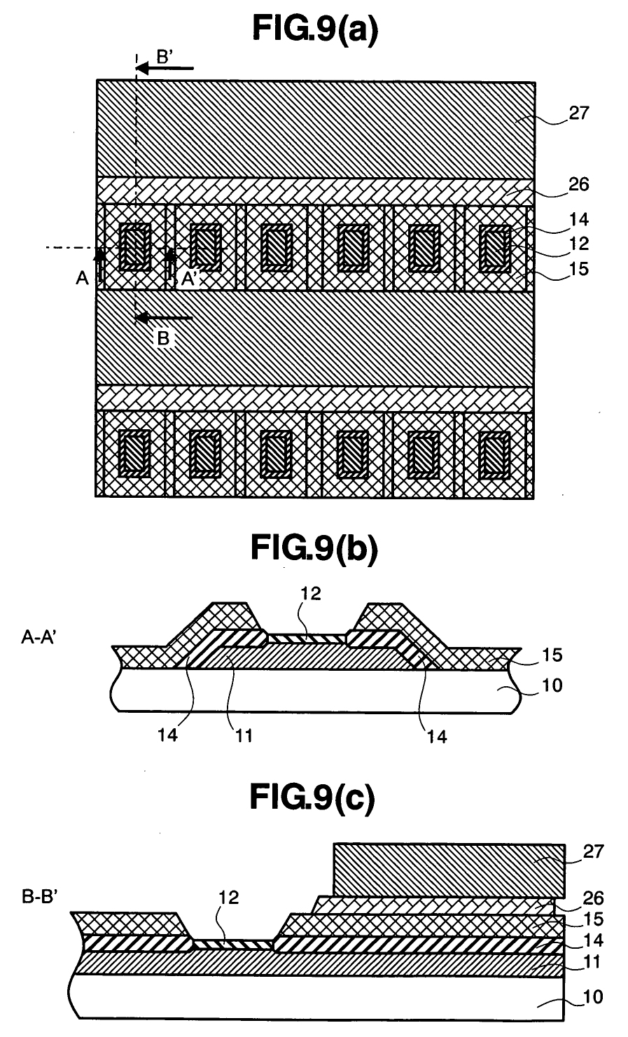

Next, as shown in FIGS. 9(a)-9(c), SiN of the second protective insulating layer 15 and other material are dry-etched to give an opening to the electron emission section (upper portion of the electron acceleration layer 12). FIG. 9(a) is a plan view, FIG. 9(b) is a sectional view taken along the A-A′ line, and FIG. 9(c) is a sectional views taken along the B-B′ line (Step 30).

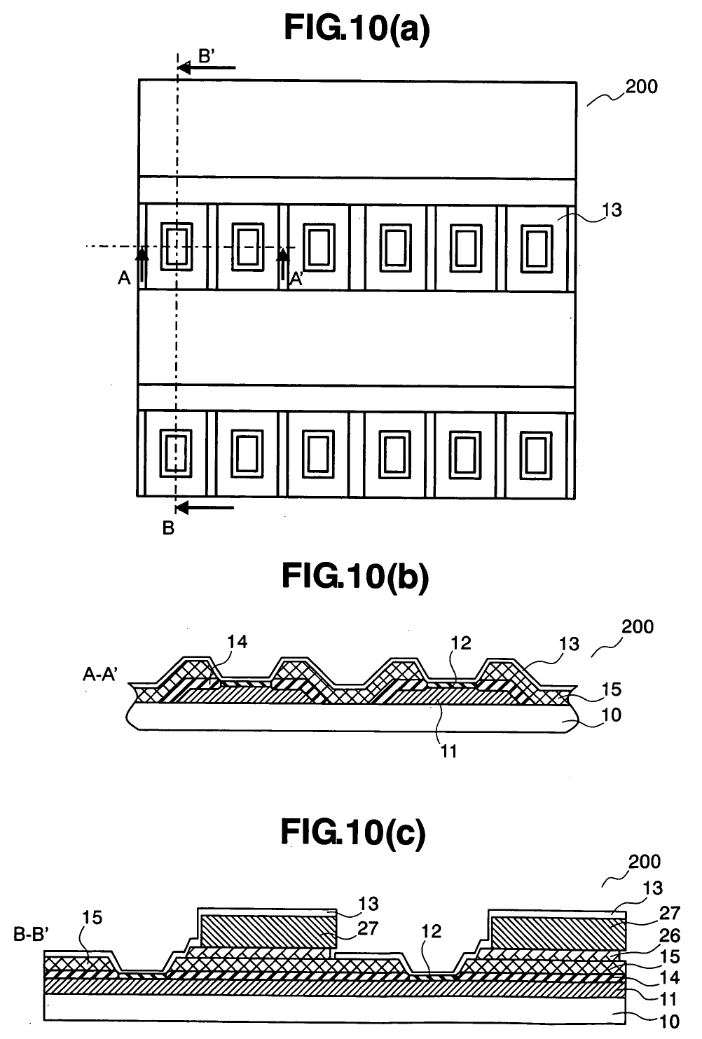

Next, the electron acceleration layer 12 is anodized again and its damage is repaired (Step 40). Next, as shown in FIGS. 10(a)-10(c), the upper electrode 13 is formed. FIG. 10(a) is a plan view, FIG. 10(b) is a sectional view taken along the A-A′ line, and FIG. 10(c) is a sectional views taken along the B-B′ line.

For example, a sputter film forming method is used for the film formation method. As the upper electrode 13, for example, a multilayer film of Ir, Pt, Au, etc. can be used. Its film thickness is a few nanometers. In this embodiment, a thickness of 5 nm is chosen. The thin upper electrode 13 formed contacts the first metal layer 26 and the second metal layer 27, realizing a structure where electric power is supplied from these layers (Step 50).

Hereafter, a substrate 200 in which the electron sources (display elements) are formed on its substrate 10 in this way is called an electron source substrate or cathode substrate. In FIG. 10(a), on the main surface of the substrate 10 (the electron source substrate 200), the plurality of upper electrodes 13 each extending along a first direction (the above-mentioned A-A′ direction) are juxtaposed in a second direction transverse to the first direction, and the plurality of bottom electrodes 11 each extending along the second direction are juxtaposed in the first direction. The plurality of bottom electrodes 11 and the plurality of upper electrodes 13 are separated by the insulating film (the first protective insulating layer) 14. In the case where feeders extending along the first direction (the above-mentioned first metal layer 26 and the above-mentioned second metal layer 27) are provided to the respective upper electrodes 13 as described above, the upper electrodes 13 may be formed as a conducting layer extended from the respective feeders to the second direction, and further the upper electrodes 13 may be separated for each of the bottom electrodes 11 (not extended along the first direction).

Whereas, in this embodiment, the display element (electron emitting element) is formed by stacking the bottom electrode 11, the electron acceleration layer 12 (a thin film area of the insulating film 14), and the upper electrode 13 in this order on the main surface of the substrate 10; in a display element of SED (Surface-conduction Electron-emitter Display), the bottom electrode 11 and the upper electrode 13 are joined through a material whose resistance is higher than those of the electrodes in the main surface of the substrate 10. Therefore, when applying this embodiment to SED, for every intersection position of the bottom electrode 11 and the upper electrode 13 (or feeder), the first conducting film is pulled out from the bottom electrode 11 along the first direction, the second conducting film is pulled out from the upper electrode 13 along the second direction, and the first conducting film and the second conducting film are brought into opposition to each other through a material whose electric resistance is higher than those of the films on the main surface of the substrate 10 or on the top surface of an insulating film formed thereon. Alternatively, the following method may be used: the first conducting film and the second conducting film are formed as one conducting film, forming processing is conducted on this film so as to cross the extension direction thereof, and the conducting film is divided by a high-resistance portion.

Next, a leak test to check whether each display element of the electron source substrate 200 obtained is normal or not is conducted. That is, it is checked weather the upper electrode 13 is short-circuited to the bottom electrode 11 due to malformation of the electron acceleration layer 12, inclusion of a foreign matter, or the like.

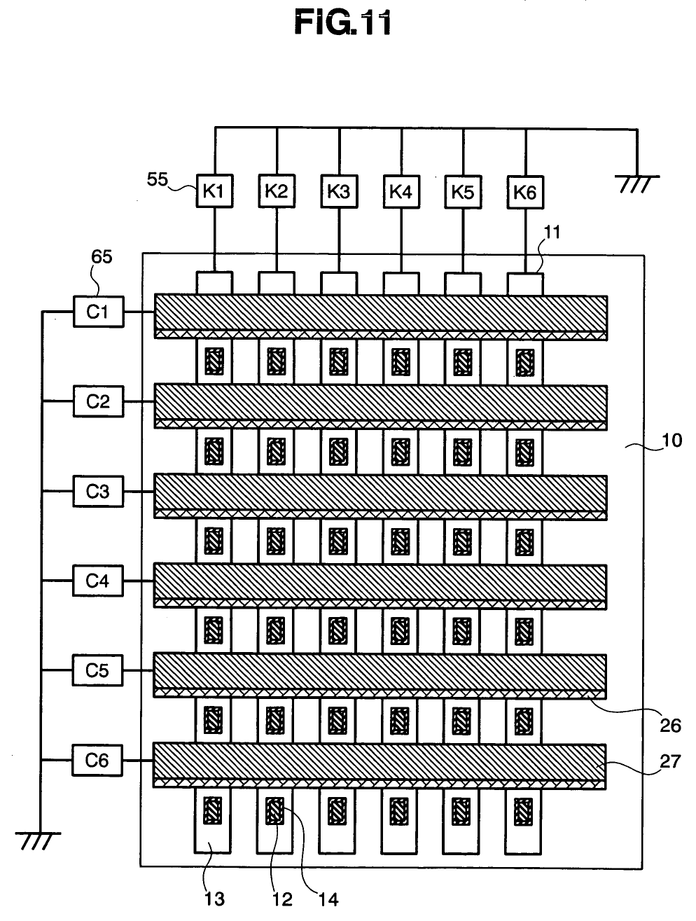

A leak test will be explained taking a case of an electron source substrate consisting of display elements of 6×6 dots. FIG. 11 is a plan view of this electron source substrate.

The upper bus electrode 27 is connected to an upper electrode drive circuit 65. The bottom electrode 11 is connected to a bottom electrode drive circuit 55. The intersection of m-th bottom electrode 11 (Km) and n-th upper bus electrode 27 (Cn) in the plan view is represented by (m, n). The line of the upper bus electrode 27 serves as a scanning line. The line of the bottom electrode 11 serves as a signal line.

In the leak test, a predetermined voltage is impressed on each line of the upper bus electrode 27 and each line of the bottom electrode 11 one by one, and it is checked whether each display element is conductive or not. Note that, when investigating one line, the electrode drive circuits of other lines are made open.

For example, first, +V1 is impressed on C1 line and 0 V is impressed on K1 line, and whether the display element becomes conductive or not is checked. When being not conductive, it can be determined that the element of (1, 1) is normal. On the other hand, if there is abnormality in the electron acceleration layer 12 and the upper electrode 13 and the bottom electrode 11 are short-circuited, a current depending on a wiring resistance flows. Therefore, when being conductive, it can be determined that the element is abnormal. Similarly, it is checked whether each element is conductive in order of the following combination, whereby the leak test can be conducted for all the display elements (electron emitting elements) (Step 60). Leak test of a display element group of C1 line (C1-K1, C1-K2, . . . C1-K6) (other C lines are made open.)

Leak test of a display element group of C2 line (C2-K1, C2-K2, . . . C2-K6) (other C lines are made open.)

Leak test of a display element group of C3 line (C3-K1, C3-K2, . . . C3-K6) (other C lines are made open.)

Leak test of a display element group of C4 line (C4-K1, C4-K2, . . . C4-K6) (other C lines are made open.)

Leak test of a display element group of C5 line (C5-K1, C5-K2, C5-K6) (other C lines are made open.)

Leak test of a display element group of C6 line (C6-K1, C6-K2, . . . C6-K6) (other C lines are made open.)

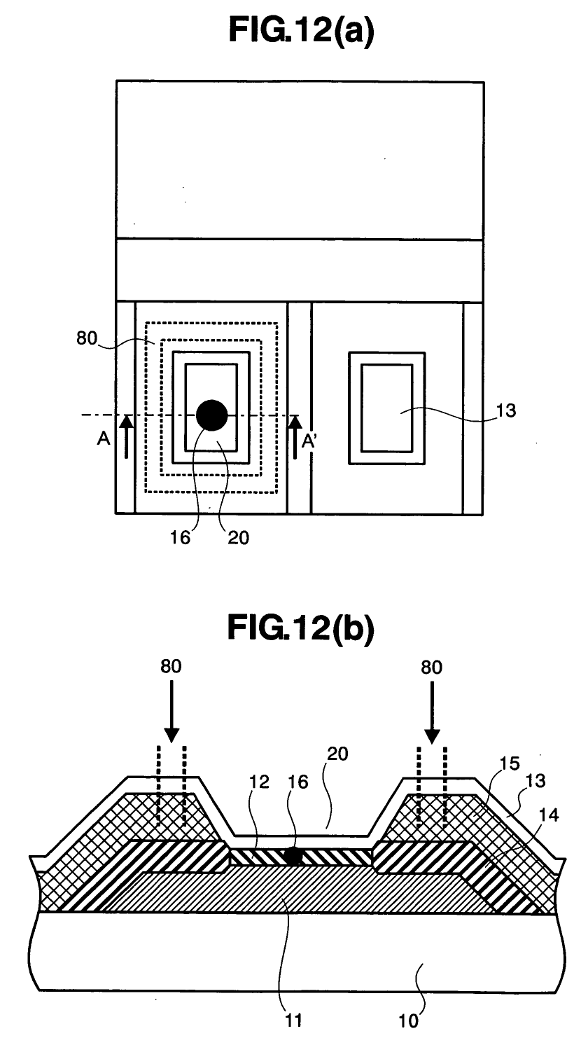

Next, repairing is conducted for the display element that was determined to be abnormal by the leak test. The repairing is done by cutting off continuity between the upper electrode 13 and the bottom electrode 11 to avoid the short circuit. FIG. 12 is a view for illustrating such repairing. FIG. 12(a) is a plan view and FIG. 12(b) is a sectional view taken along A-A′ line. The reference numeral 16 denotes a defective portion caused by inclusion of a foreign matter etc. Assume this defect causes short circuit between the upper electrode 13 and the bottom electrode 11.

Cutoff of the continuity between the upper electrode 13 and the bottom electrode 11 can be attained by excising a portion 80 shown by the dashed line of FIGS. 12(a) and 12(b) by laser. As the laser, the third harmonic (355 nm) of the YAG laser, the forth harmonic (266 nm) thereof, etc. can be used.

Specifically, as is shown in the figure, a portion of the upper electrode 13 is excised to enclose the electron emission section 20 thereby. The depth of excision may be any depth at which the upper electrode 13 is cut off. Preferable is a depth that does not reach the substrate 10 and the bottom electrode 11, and more preferable is a depth that does not reach the second protective insulating layer 14. If the depth of excision is formed to stop in the second protective insulating layers 15, the continuity between the upper electrode 13 and the bottom electrode 11 can be avoided. Moreover, a portion of excision can be controlled to the minimum. Further, it will not damage lower layers.

Note that a region of excision only needs to isolate a short-circuited portion from the electrode. Therefore, if the short-circuited portion can be specified, the short-circuited portion may be excised by laser. Alternatively, the whole electron emission section including the electron acceleration layer 12 may be excised.

Next, a process (Steps 80 to 120) where a display panel is made using the electron source substrate (cathode substrate) 200 made as described above will be explained.

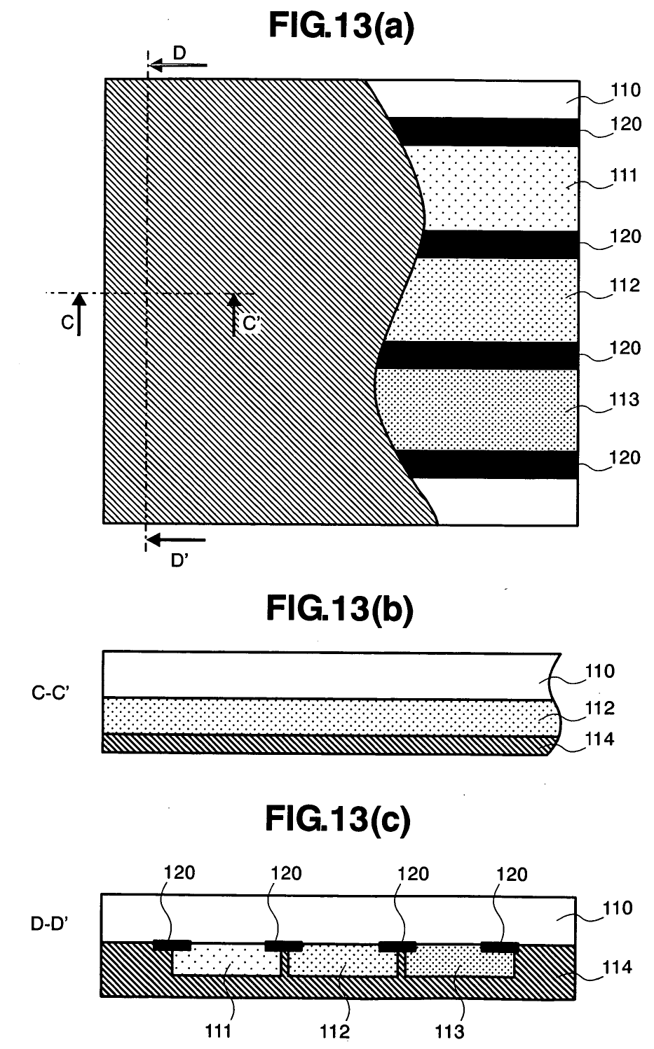

First, a display side substrate (anode substrate) 100 is made. FIG. 13(a) is a plan view of the anode substrate 100, FIG. 13(b) is a sectional view taken along C-C′ line, and FIG. 13(c) is a sectional view taken along D-D′ line.

Translucent glass etc. is used for a faceplate 110. First, a black matrix 120 for enhancing the contrast of the display device is formed on the faceplate 110, Specifically speaking, a solution prepared by mixing PVA (polyvinyl alcohol) and sodium dichromate is applied to the faceplate 110 and sensitized by irradiating ultraviolet rays on a portion other than a portion where the black matrix 120 is intended to be formed. Then, a non-exposed portion is removed, a solution in which graphite powder is solved is applied, and then PVA is patterned by a lift-off process (Step 80).

Next, a red fluorescent material 111 is formed. Specifically speaking, an aqueous solution prepared by mixing the fluorescent material particle with PVA (polyvinyl alcohol) and ammonium dichromate is applied to the faceplate 110, and a portion where the fluorescent material is intended to be formed is irradiated with ultraviolet rays and sensitized. Then, a non-exposed portion is removed by running water. Thus, the red fluorescent material 111 is patterned. As for an actual pattern, the red fluorescent material is patterned in the form of a stripe as shown in FIGS. 13(a)-13(c). Similarly, a green fluorescent material 112 and a blue fluorescent material 113 are formed. As fluorescent materials, for example, it is recommendable to use Y₂O₂S: Eu (P22-R) for red, ZnS: Cu, Al (P22-G) for green, and ZnS: Ag, Cl (P22-B) for blue. Since the distance between the faceplate 110 and the substrate 10 is as large as about 1 to 3 mm, an acceleration voltage impressed on a metal back 114 can be set to a high voltage of 3 to 6 kV. Therefore, fluorescent materials for cathode-ray tubes (CRT) can be used for the fluorescent materials of this embodiment (Step 90).

Subsequently, after forming a filming film with a film, such as nitrocellulose, and Al is evaporated on the whole faceplate 110 to a film thickness of about 75 nm to prepare the metal back 114. This metal back 114 acts as an accelerating electrode. After that, the faceplate 110 is heated to about 400° C. in the air, so that organic substances of the filming film, PVA, etc. are decomposed by heating (Step 100).

The display side substrate 100 is completed as described above.

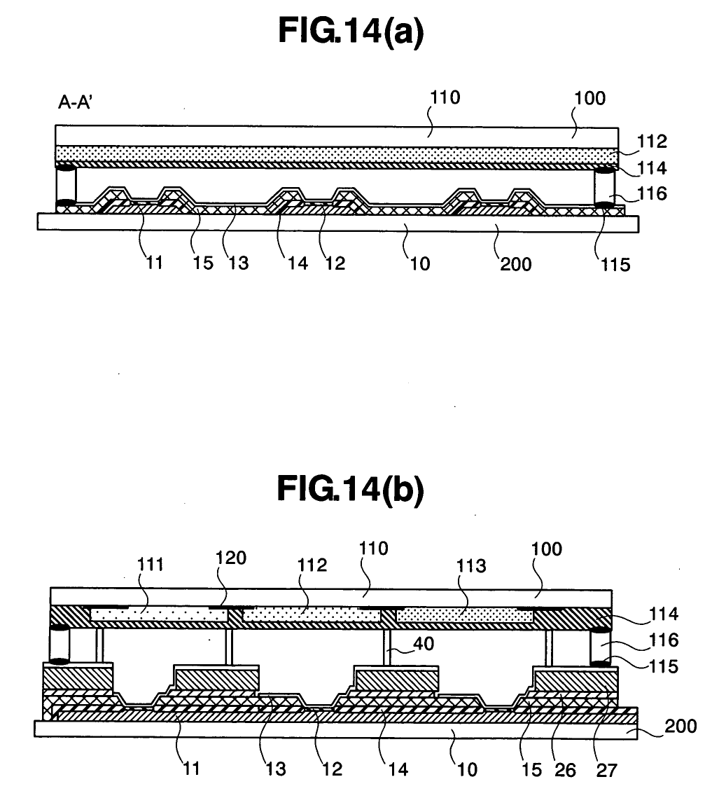

Next, the display side substrate (anode substrate) 100 thus manufactured and the electron source substrate 200 (cathode substrate) are stuck together. In the display panel (display device) built up in this way, as shown in FIGS. 14(a), 14(b), the display side substrate 100 and the electron source substrate 200 (consisting of the substrate 10 and a structure formed on the main surface of the substrate 10) are joined through a sealing member (a frame 116), their main surfaces being separated with a gap and in opposition to each other. FIG. 14(a) shows a cross-section obtained by cutting the display panel along the A-A′ line of FIG. 10(a) showing the main surface of the electron source substrate 200 that is built in the display panel (extension direction of the upper electrode 13). FIG. 14(b) shows a cross-section obtained by cutting the display panel along the B-B′ line of FIG. 10(a) (extension direction of the bottom electrode 11). As shown in these figures, the display side substrate 100 and the electron source substrate 200 are sealed through the surrounding frame 116 using a frit glass 115. Plural electron emitting elements that are formed on the main surface of the electron source substrate 200 and serve as pixels of the display device (each element being made up of a multilayer structure consisting of the upper electrode 11, the electron acceleration layer 12, and the upper electrode 13) are disposed in a space surrounded by the main surface of the electron source substrate 200, the main surface of the display side substrate 100, and the sealing member (the frame 116).

The spacers 40 are disposed between the faceplate 110 and the substrate 10 and their heights are adjusted so that the distance therebetween becomes about 1 to 3 mm. In this figure, the spacers 40 are set for every dot that emits light of R (red), G (green), and B (blue) for purposes of illustration. However, actually the number of spacers 40 (density) may be reduced as long as the spacers 40 can withstand mechanical strength. For example, the spacers 40 may be set roughly every 1 cm (Step 110).

The sealed panel is evacuated to a vacuum of about 10⁻⁷ Torr and then sealed airtightly. After being sealed, a getter is activated to maintain the vacuum inside the panel. For example, in the case of a getter material whose principal component is Ba, a getter film can be formed by RF induction heating etc. Alternatively, a non-evaporation type getter whose principal component is Zr may be used (Step 120).

In the foregoing, the manufacturing process of the display panel was explained. As described above, the manufacturing process of the display panel of this embodiment includes a step of, when the electron source existing on the electron source substrate 200 has a defect, repairing the electron source (Step 70). Next, an effect obtained by providing such a repairing process (Step 70) will be explained.

First, an operation of the display panel in the case where all the electron sources have no defect will be explained.

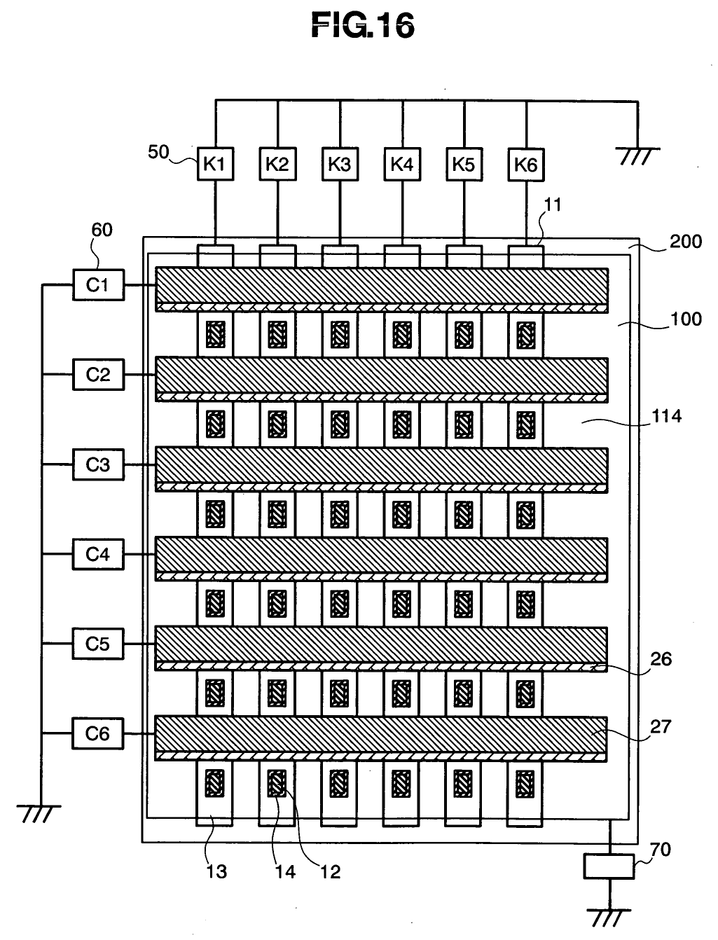

FIG. 16 is a connection diagram to the drive circuit of the display panel manufactured as described above. FIG. 16 is a plan view of the display panel when viewed from the display side. For the ease of understanding, the display side substrate 100 and a part of the upper electrode 13 of the electron source substrate 200 are not drawn in full.

The upper bus electrode 27 is connected to an upper electrode drive circuit 60. The bottom electrode 11 is connected to a bottom electrode drive circuit 50. The bottom electrode 11 serves as the signal line side electrode. The upper bus electrode 27 serves as the scanning line side electrode. The intersection of the m-th bottom electrode 11 (represented by Km) and the n-th 20; upper bus electrode 26 (represented by Cn) in the plan view will be represented by (m, n). An acceleration voltage 70 of about 3 to 6 kV is always impressed on the metal back 114.

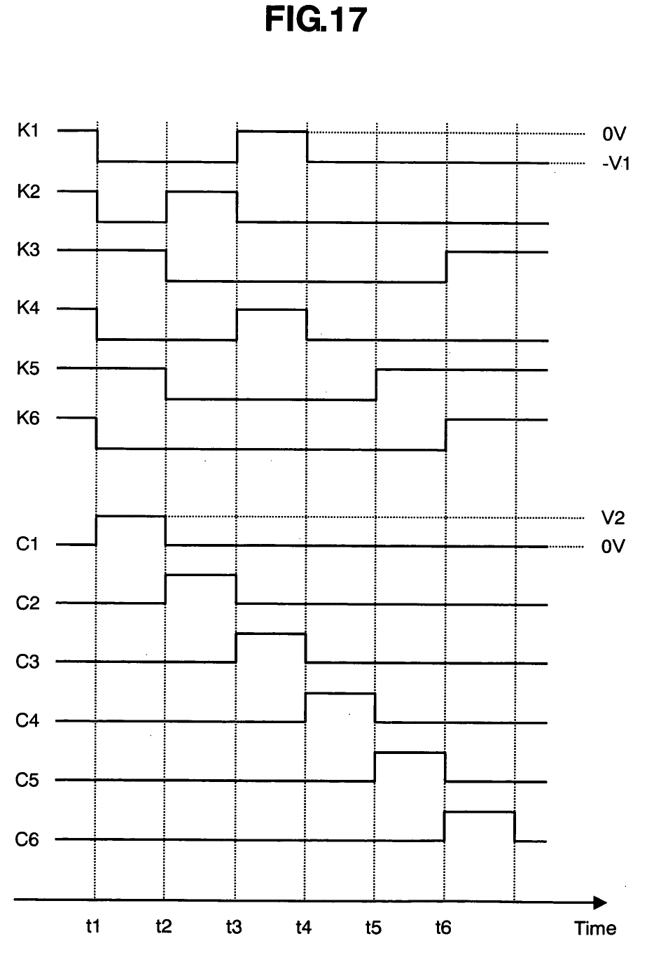

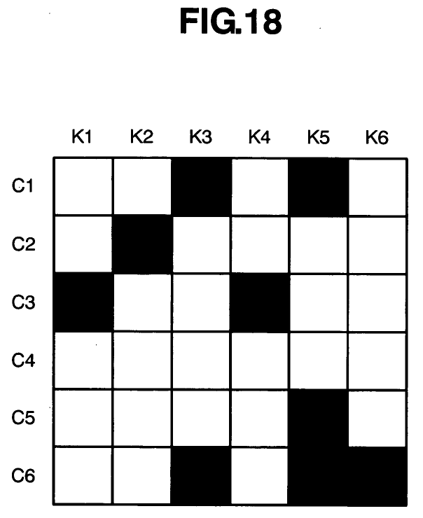

FIG. 17 shows one example of voltage waveforms generated by respective drive circuits. FIG. 18 shows what is displayed on the display screen when the voltages are impressed as shown in FIG. 17. Assume an electron emission starting voltage of the electron source is set to (V1+V2).

At time t0, since any electrodes have a voltage of zero, no electrons are emitted.

At time t1, a voltage of −V1 is impressed on K1, K2, K4, and K6 of the bottom electrodes 11 and a voltage of +V2 is impressed on C1 of the upper electrode 26. In this case, a voltage of (V1+V2) is impressed between the bottom electrode 11 and the upper electrode 13 at intersections (1, 1), (2, 1), (4, 1), and (6, 1). Therefore, electrons are emitted to the vacuum from the electron emission sources at these points. The emitted electrons are accelerated by the acceleration voltage 70 impressed on the metal back 114, and subsequently incident on the fluorescent material, which is made to emit light. As a result, as shown in FIG. 18, the intersections (1, 1), (2, 1), (4, 1), and (6, 1) turn on.

At time t2, a voltage of −V1 is impressed on K1, K3, K4, K5, and K6 of the bottom electrodes 11 and a voltage of V2 is impressed on C2 of the upper bus electrode 27, and then the intersections (1, 2), (3, 2), (4, 2), (5, 2), and (6, 2) turn on. Thus, by changing a signal impressed on the bottom electrodes 11, a desired image or information can be displayed. Moreover, by changing the magnitude of the impressed voltage V1 on the upper bus electrode 27, a gray-scale image can be displayed.

Next, in the case where any one of the electron sources on the electron source substrate has a defect, a case where such an electron source is not repaired will be explained.

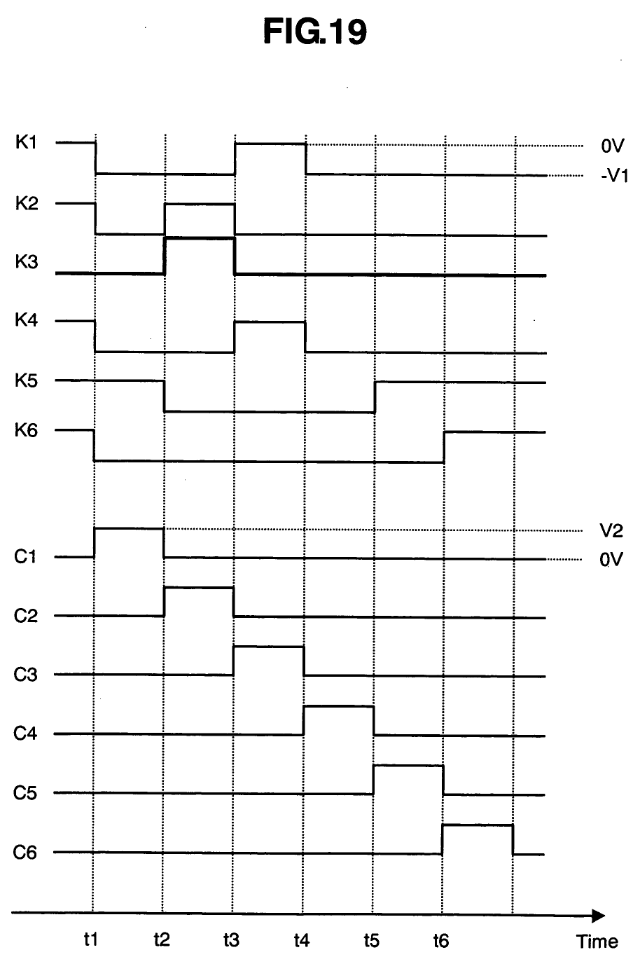

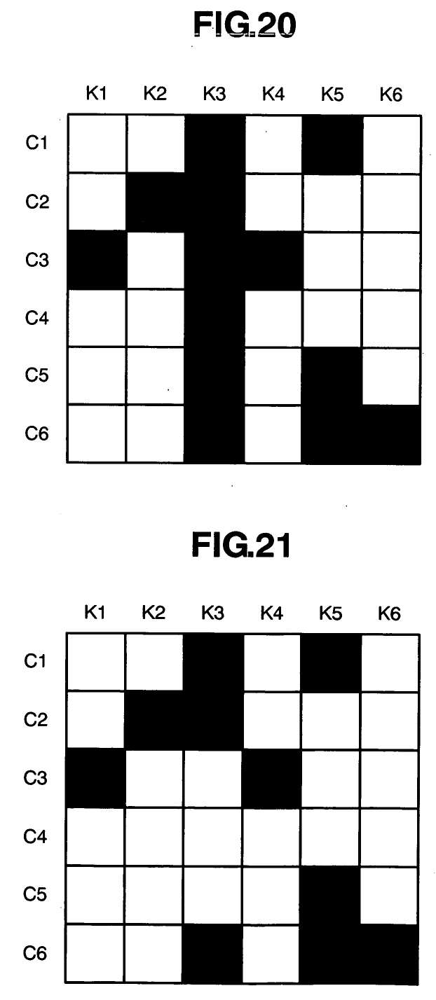

For example, in the electron source substrate 200 shown in FIG. 16, assume the electron source of (3, 2) has a defect, which causes and the upper electrode 13 and the bottom electrode 11 to be short-circuited. In this case, it becomes impossible to impress a predetermined voltage (−V1) to all the electron sources on K3 line. Therefore, even if a voltage is intended to be impressed as shown in FIG. 17, an actual generated voltage waveform becomes as shown in FIG. 19. That is, on K3 line, any electron sources cannot have an electron emission starting voltage (V1+V2). Therefore, on the display screen, display elements on K3 line will not turn on as shown in FIG. 20, and defects will appear in a line.

Next, a case where a process of repairing an electron source with a defect is provided in the manufacturing process will be explained. In the repairing process (Step 70) in the manufacturing process of this embodiment, a short-circuited portion is isolated by excising the upper electrode in the surrounding of the short-circuited portion, as shown in FIGS. 12(a) and 12(b), and consequently the continuity between the upper electrode 13 and the bottom electrode 11 is cut off. Therefore, even when there is a defect in the electron source of (3, 2), the defect does not affect other electron sources on K3 line. A predetermined voltage (−V1) can be impressed on the bottom electrodes 11 of the other electron sources. Therefore, as shown in FIG. 21, pixels that could not be displayed will not appear in a line. That is, the electron sources that are originally normal can be operated normally.

In the foregoing, one embodiment of the present invention was described. Various modifications are possible for the above-mentioned embodiment within the range of the gist of the present invention.

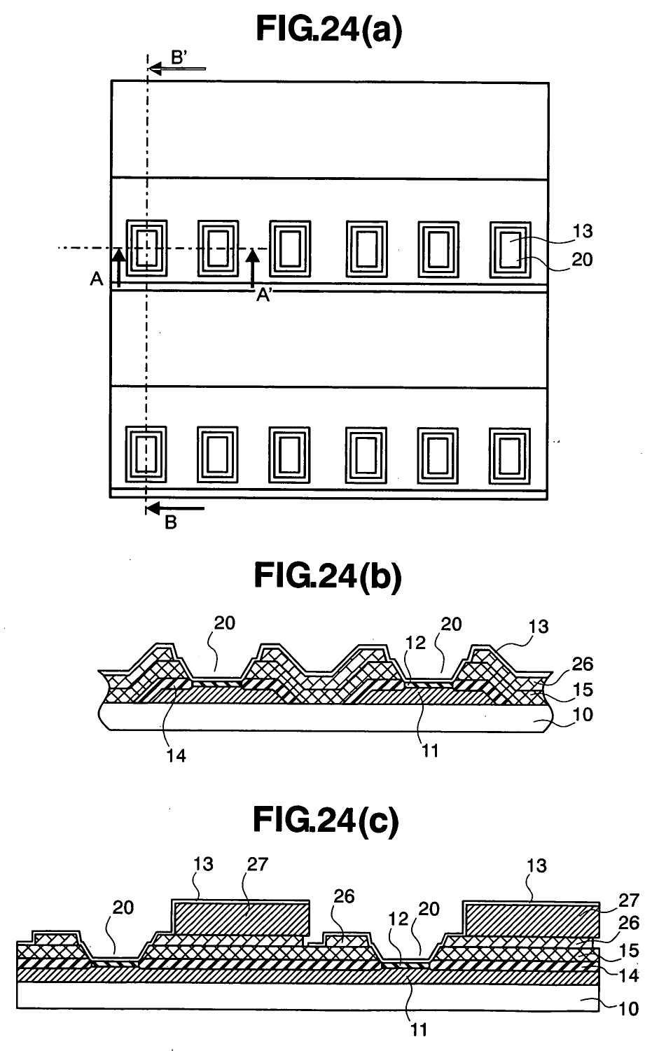

For example, the structure of the electron source may be formed in such a way that the upper bus electrode 26 encloses the electron emission section 20 made up of the electron acceleration layer 12, as shown in FIGS. 24(a)-24(c). FIG. 24(a) is a plan view, FIG. 24(b) is a sectional view taken along A-A′ line, and FIG. 24(c) is a sectional views taken along B-B′ line. With this structure, a voltage can be impressed uniformly on the upper electrodes 13 above the electron acceleration layer 12.

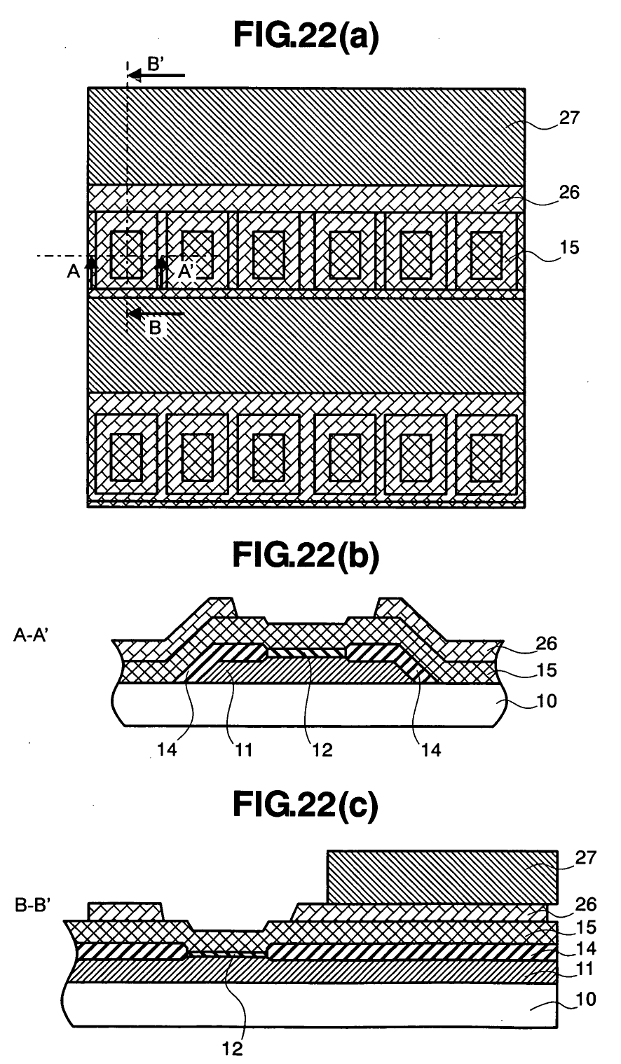

Such an electron source substrate can be manufactured as follows. In the above-mentioned manufacturing process, when the upper bus electrode (the first metal layer 26 and the second metal layer 27) is fabricated, the fabrication is done as shown in FIGS. 22(a)-22(c) instead of fabricating as shown in FIG. 8. That is, the first metal layer 26 is formed so as to surround the electron emission section.

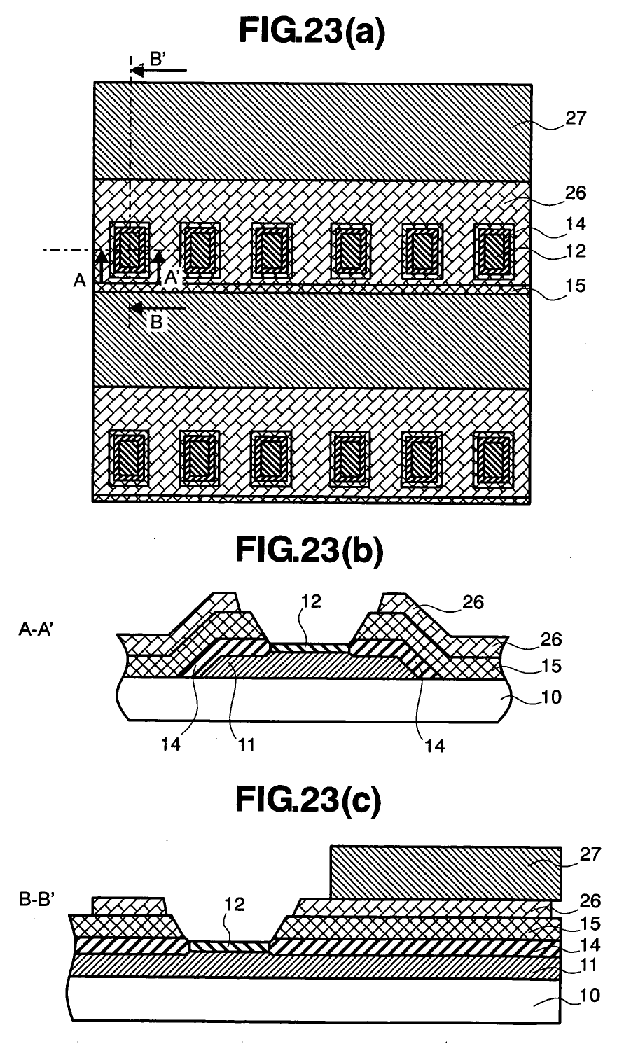

Then, as shown in FIGS. 23(a)-23(c), SiN etc. of the second protective insulating layer 15 is dry-etched to make an opening in the electron emission section. FIG. 23(a) is a plan view, FIG. 23(b) is a sectional view taken along A-A′ line, and FIG. 23(c) is a sectional view taken along B-B′ line (Step 30).

Next, the electron acceleration layer 12 is anodized again to repair its damage (Step 40). Next, as shown in FIGS. 24(a)-24(c), the upper electrode 13 is formed. FIG. 24(a) is a plan view, FIG. 24(b) is a sectional view taken along A-A′ line, and FIG. 24(c) is a sectional view taken along B-B′ line.

In this way, the electron source substrate in which the upper bus electrode (the first metal layer 26) was formed so as to surround the electron emission section 20 is made.

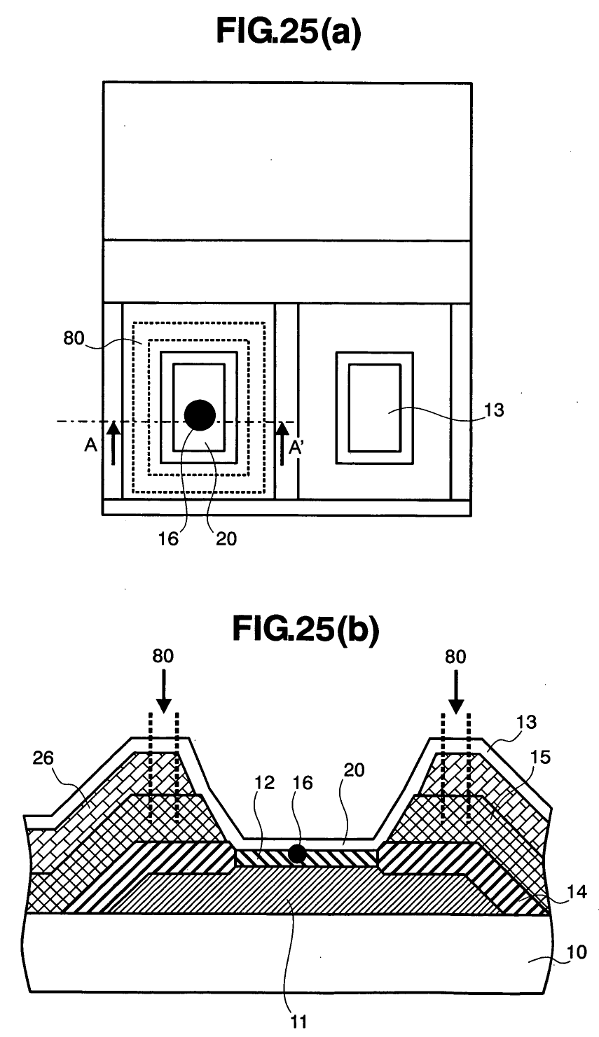

A method for repairing an electron source with a defect in such an electron source substrate will be explained. As described above, repairing is done by cutting off the continuity between the upper electrode 13 and the bottom electrode 11 to avoid the short circuit. FIG. 25 is a view for illustrating such repairing. FIG. 25(a) is a plan view, and FIG. 25(b) is a sectional view taken along A-A′ line. The reference numeral 16 denotes a defective portion caused by inclusion of a foreign matter etc. Assume this defect causes the upper electrode 13 to be short-circuited to the bottom electrode 11.

Cutoff of the continuity between the upper electrode 13 and the bottom electrode 11 can be attained by excising the portion 80 (portion to be excised) shown by a dashed line of FIG. 25 by laser.

Specifically speaking, as shown in FIG. 25(a), the upper electrode 13 and the first metal layer 26 are excised so that the excised portion encloses the electron emission section (the electron acceleration layer 12). The depth of excision may be a depth at which the upper electrode 13 is cut off and the first metal layer 26. However, preferable is a depth that does not reach both the substrate 10 and the bottom electrode 11, and more preferable is a depth that does not reach the second protective insulating layer 14. If the depth of excision stops in the second protective insulating layers 15, the continuity between the upper electrode 13 and the bottom electrode 11 can be avoided. Moreover, with this depth, the portion of excision can be made a minimum. Furthermore, this depth does not damage lower layers.

In the foregoing, the one embodiment of the present invention was described including the modifications. According to the above-mentioned embodiment, generation of the pixels that could not be displayed in a line can be inhibited.

Note that the present invention is not limited to the field emission display whose electron source is of the MIM type, and can be applied to the field emission displays of the other types that were described above.

Moreover, even if the display element is not the field emission type electron source, the present invention may be applied to the element as long as a display substrate is provided with display elements at portions where the scanning lines intersect the signal lines. That is, for a display element whose scanning line side electrode and signal line side electrode is short-circuited, the continuity between the scanning line side electrode and the signal line side electrode is cut off. This can prevent pixels from being missing in a line.

While we have shown and described several embodiments in accordance with the present invention, it is understood that the same is not limited thereto but is susceptible of numerous changes and modifications as known to those skilled in the art, and we therefore do not wish to be limited to the details shown and described herein but intend to cover all such changes and modifications as are encompassed by the scope of the appended claims.

What is claimed is:

1. A method for repairing a display device having a substrate comprising electron sources each of which has a structure such that a first electrode, an insulating layer, and a second electrode are stacked in this order,
wherein
for an electron source having the first electrode and the second electrode short-circuited, continuity between the first electrode and the second electrode is cut off.

2. The method for repairing a display device according to claim 1, wherein
the cutoff of continuity between the first electrode and the second electrode is done by excising the second electrode in the surrounding of the short-circuited portion.

3. The method for repairing a display device according to claim 1, wherein
the cutoff of continuity between the first electrode and the second electrode is done by excising the second electrode in the surrounding of an electron emission portion of the electron source.

4. The method for repairing a display device according to claim 2, wherein
the excision of the second electrode is conducted to such a depth as does not reach the first electrode.

5. The method for repairing a display device according to claim 2, wherein
the excision of the second electrode is done by laser.

6. The method for repairing a display device according to claim 2, wherein
the first electrode is a signal line side electrode and the second electrode is a scanning line side electrode.

7. A method for repairing a display device comprising
a first substrate having a main surface on which display elements in each of which a scanning line side electrode and a signal line side electrode are jointed through an area having electric resistance higher than those of the electrodes are provided at respective portions at each of which the scanning line intersects the signal line, and
a second substrate being disposed in opposition to the main surface of the first substrate and on which a material layer for emitting light by electrons emitted from the display elements and incident thereon is formed,
wherein
for the display element such that the scanning line side electrode and the signal line side electrode are short-circuited, continuity between the scanning line side electrode and the signal line side electrode is cut off.

8. A method for manufacturing an electron emission type display device, comprising the steps of:
obtaining an electron source substrate by forming a plurality of electron sources on a main surface of the substrate to be built into a display panel of the display device;
checking a defect of each electron source formed on the main surface of the electron source substrate;
for the electron source with the defect;
cutting off continuity between the scanning line side electrode and the signal line side electrode of the electron source with the defect; and
sticking the electron source substrate thus obtained to a display side substrate.
